(19) United States
(12) Patent Application Publication
(10) Pub. No.: US 2008/0174377 A1
(43) Pub. Date: Jul. 24, 2008

(54) THIRD OVERTONE CRYSTAL OSCILLATOR

(75) Inventors: Toshikatsu Makuta, Saitama (JP); Handong Yan, Saitama (JP)

Correspondence Address: CANTOR COLBURN, LLP, 20 Church Street, 22nd Floor, Hartford, CT, 06103, US

(73) Assignee: NIHON DEMPA KOGYO CO., LTD., Tokyo (JP)

(21) Appl. No.: 12/015,800

(22) Filed: Jan. 17, 2008

(30) Foreign Application Priority Data
Jan. 18, 2007 (JP) 2007-009577

(51) Int. Cl. H03B 5/36

(52) U.S. Cl. 331/116 R

(57) ABSTRACT

A third overtone crystal oscillator includes an oscillator IC and a crystal element. The oscillator IC has an emitter-grounded transistor for oscillation, a first capacitor connected to the base of the transistor via a dc blocking capacitor and to the ground potential; and a second capacitor connected between the collector of the transistor and the ground potential. Both ends of crystal element are connected to the non-grounded ends of the first and second capacitors, respectively. An inductor, which forms a parallel resonant circuit with the first capacitor, is provided as a discrete element separated from the oscillator IC, and the parallel resonance frequency of the parallel resonant circuit formed by the first capacitor and the inductor is set higher than an oscillation frequency of a fundamental wave of the crystal element and lower than an oscillation frequency of a third overtone of the crystal element.

### BACKGROUND OF THE INVENTION

1. Field of the Invention

The present invention relates to a third overtone crystal oscillator, and particularly to a third overtone crystal oscillator incorporating an IC (integrated circuit) for the fundamental wave oscillation of a crystal element.

2. Description of the Related Art

Crystal oscillators in which a quartz crystal element and an integrated circuit provided with an oscillation circuit using the crystal element are combined have high frequency stability. The crystal oscillators are therefore used as a reference source for frequency and time in various kinds of electronic devices. As one type of the ICs used in such a crystal oscillator, there is an IC known as CF 5036 series and CF 5037 series manufactured by Seiko NPC Corporation, Tokyo, JAPAN (http://www.npc.co.jp). This IC is used in a crystal oscillator for optical digital networks.

In recent years, in order to double the transmission capacity, an crystal oscillator for optical digital networks which has an oscillation output in 300-MHz band has been demanded to replace the current one having oscillation output in 150-MHz band.

FIG. 1A is a circuit diagram illustrating an example of the conventional crystal oscillator, and FIG. 1B is a plan view of the crystal oscillator with a cover removed therefrom.

The crystal oscillator comprises oscillator IC 1 in which an oscillation circuit is integrated, and quartz crystal element (quartz crystal blank) 2. Oscillator IC 1 and crystal element 2 are housed in a recess of the container 3. Here, it is assumed that oscillator IC is one in CF 5036 series and CF 5037 series manufactured by Seiko NPC Corporation. Such oscillator IC 1 is configured by integrating at least transistor Tr for oscillation, constant current source I, first and second capacitors C1 and C2 for oscillation, and dc (direct-current) blocking capacitor Cs. Transistor Tr is grounded at the emitter thereof and has bias resistor R between the collector and the base.

Constant current source I is supplied with power supply voltage Vcc and generates a constant current. Constant current source I supplies the constant current to the junction point between the collector of Tr and bias resistor R. First capacitor C1 for oscillation is connected between the base and the ground potential. Second capacitor C2 is connected between the collector and the ground potential. Direct-current blocking capacitor Cs is inserted between the junction point, which is between the base and bias resistor R, and first capacitor C1. Oscillator IC 1 has output terminal Vout which is connected to the collector of transistor Tr.

Oscillator IC 1 is die-bonded to the inner bottom surface of the recess of container 3, and IC terminals of this IC are connected to step portions formed in the opposite longitudinal inner walls of the recess by means of wire-bonded gold wires 4. Crystal element (crystal blank) 2 is an AT-cut quartz crystal blank, for example, and has excitation electrodes (not shown) on both principal surfaces. Leading electrodes extend from the excitation electrode to the opposite sides of one end of crystal element 2. Crystal element 2 is held in the recess of container 3 by fixing the opposite sides of the one end of crystal element 2, to which the leading electrodes are extended, to the step portion of the inner wall in the one end portion in the longitudinal direction of container 3. Crystal blank 2 is electrically connected between the non-grounded ends of first and second capacitors C1, C2 via a pair of IC terminals provided on oscillator IC 1.

In such a crystal oscillator, the operation frequency range of the oscillator circuit incorporated in oscillator IC 1 can be varied by changing the circuit parameters or the like of the oscillator circuit. The series of the ICs covers the operating frequency range generally from 50 to 700 MHz as a whole. Therefore, if crystal element 2 having an oscillation frequency falling within this range is electrically connected to oscillator IC 1 (i.e., oscillator circuit), a crystal oscillator having an oscillation frequency within the range of 50 to 700 MHz can be provided.

If an IC in the CF5036 series and the CF5037 series manufactured by Seiko NPC Corporation described above is used as oscillator IC 1, oscillation output up to 700 MHz can be obtained when the crystal element operates in the fundamental wave oscillation. However, in the case of the third overtone oscillation, the oscillation frequency is limited up to 250 MHz. Therefore, it is not possible to obtain the oscillation output in the 300-MHz band in the case of the third overtone oscillation.

An oscillation frequency in the 300-MHz band can be obtained by operating crystal element 2 in the fundamental wave vibration mode in 300-MHz band in compliance with the standard of oscillator IC 1 (i.e., oscillator circuit). However, the oscillation frequency of AT-cut quartz crystal element (crystal blank) 2 is inversely proportional to the thickness thereof, and the thickness of the crystal element is about 5.6 μm when the crystal element has a fundamental wave oscillation frequency of 300 MHz. It is difficult to manufacture such a thin crystal element with a high yield. On the other hand, when it is assumed that an oscillation frequency of 300 MHz could be obtained by the third overtone oscillation, a crystal blank having a fundamental wave oscillation frequency of approximately 100 MHz can be used. Such a crystal blank has a thickness of about 17 μm and is easily manufactured. The stable yield of the crystal blank can be ensured.

### SUMMARY OF THE INVENTION

An object of the present invention is to provide a crystal oscillator which enables the third overtone oscillation using an oscillator IC in which an oscillator circuit for the fundamental wave of a crystal element is integrated.

The object of the present invention can be achieved by a third overtone crystal oscillator, comprising: an oscillator IC; and a crystal element, wherein the oscillator IC comprises: an transistor for oscillation which is grounded at an emitter thereof, a bias resistor being connected between a collector and a base of the transistor, and a constant current being supplied from a constant current source to a junction point between the collector and the bias resistor; a first capacitor for oscillation connected to the base via a dc blocking capacitor and to a ground potential; and a second capacitor for oscillation connected between the collector and the ground potential, wherein one end of the crystal element is connected to a non-grounded end of the first capacitor while the other end of the crystal element is connected to a non-grounded end of the second capacitor, wherein an inductor, which forms a parallel resonant circuit with the first capacitor, is provided as a discrete element separated from the oscillator IC, and wherein a parallel resonance frequency of the parallel resonant circuit formed by the first capacitor and the inductor is set higher than an oscillation frequency of a fundamental wave of the crystal element and lower than an oscillation frequency of a third overtone of the crystal element.

With such an arrangement, the impedance of the parallel resonant circuit composed of the first capacitor and the inductor dominates the impedance of the oscillator circuit viewed from the opposite terminals of the crystal element in the parallel resonance frequency range. Therefore, if the parallel resonance frequency is set higher than the oscillation frequency of the fundamental wave of the crystal element, the negative resistance does not occur in the oscillator circuit at frequencies equal to or lower than the oscillation frequency of the fundamental wave, and therefore, the fundamental oscillation can be suppressed. Furthermore, since the negative resistance occurs in the oscillator circuit at frequencies equal to or higher than the parallel resonant frequency, the third overtone oscillation, which involves the highest negative resistance, can be easily achieved when the parallel resonant frequency is set lower than the oscillation frequency of the third overtone. The oscillation output of the third overtone oscillation can be easily obtained.

### BRIEF DESCRIPTION OF THE DRAWINGS

FIG. 1A is a circuit diagram of a crystal oscillator according to the prior art;

FIG. 1B is a plan view of the crystal oscillator shown in FIG. 1A with a cover removed therefrom;

FIG. 2A is a circuit diagram of a third overtone crystal oscillator according to an embodiment of the present invention;

FIG. 2B is a plan view of the crystal oscillator shown in FIG. 2A with a cover removed therefrom; and

FIG. 3 is a graph of negative resistance characteristics which illustrates the operation principle of the crystal oscillator shown in FIG. 2A.

### DETAILED DESCRIPTION OF THE PREFERRED EMBODIMENT

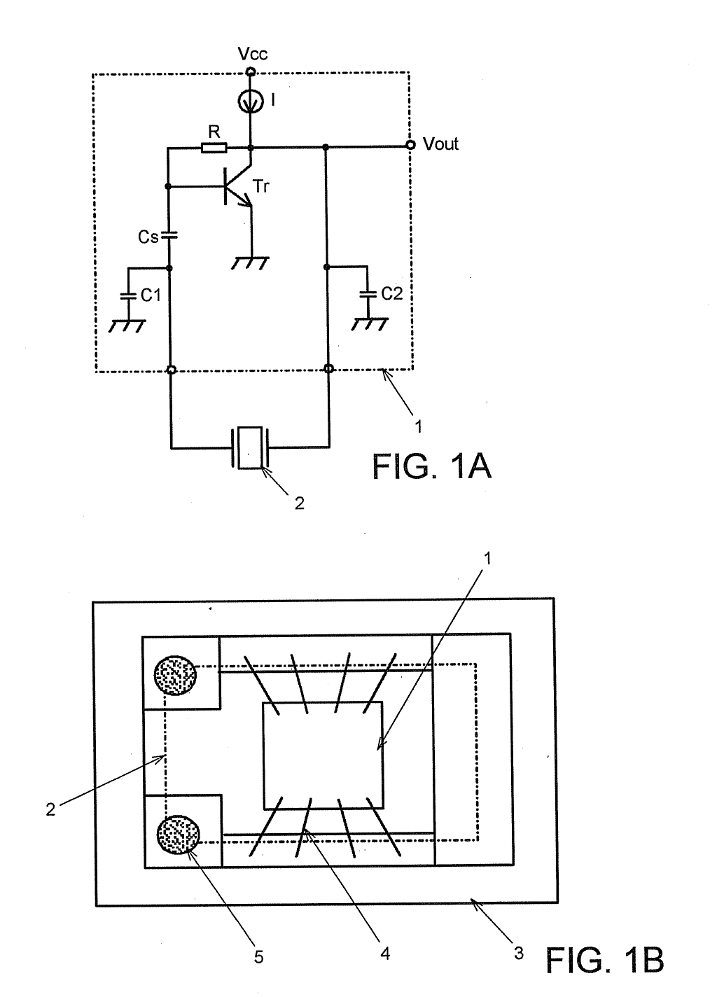

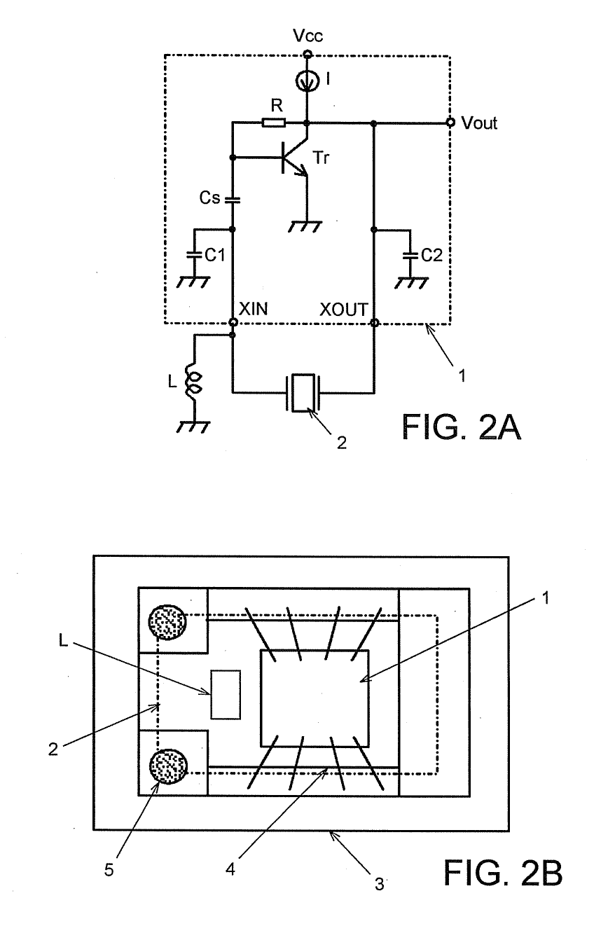

In FIGS. 2A and 2B which illustrate a third overtone crystal oscillator according to one embodiment of the present invention, components identical to those in FIGS. 1A and 1B are designated the same reference numerals, and the description on those components will be simplified or omitted.

As described earlier, the crystal oscillator comprises oscillator IC 1 and crystal element (crystal blank) 2, which are housed in container 3. Oscillator IC 1 operates in the fundamental wave oscillation mode and is, for example, the CF5036D1 manufactured by Seiko NPC Corporation, which has an operating frequency range of 250 to 400 MHz. The internal equivalent circuit of oscillator IC 1 is the same as that shown in FIG. 1A. This oscillator IC 1 comprises and integrates at least transistor Tr for oscillation, constant current source I, first and second oscillation capacitors C1 and C2 for oscillation, and dc (direct-current) blocking capacitor Cs.

Transistor Tr is grounded at the emitter and has bias resistor R between the collector and the base. Constant current source I is supplied with power supply voltage Vcc and supplies the constant current to the connection point between the collector and bias resistor R. One end of first capacitor C1 is connected to the base via dc blocking capacitor Cs while the other end of first capacitor is connected to the ground potential. Second capacitor C2 is connected between the collector and the ground potential. Oscillator IC 1 is provided with a pair of terminals XIN, XOUT. Terminal XIN is connected to the non-grounded end of first capacitor C1 while terminal XOUT is connected to the non-grounded end of second capacitor C2. The opposite ends of crystal element (crystal blank) 2 are connected to terminals XIN, XOUT, respectively.

In this embodiment, inductor L is connected in parallel with first capacitor C1 to form a parallel resonant circuit. Inductor L is a discrete element (i.e., chip element) separated from oscillator IC 1. Inductor L is fixed to the inner bottom surface of the recess of container 3 and housed in the recess together with oscillator IC 1 and crystal blank 2. The parallel resonance frequency of this parallel resonant circuit first formed by capacitor C1 and inductor L is set higher than oscillation frequency f1 of the fundamental wave of crystal element 2 and lower than oscillation frequency f3 of the third overtone of crystal element 2.

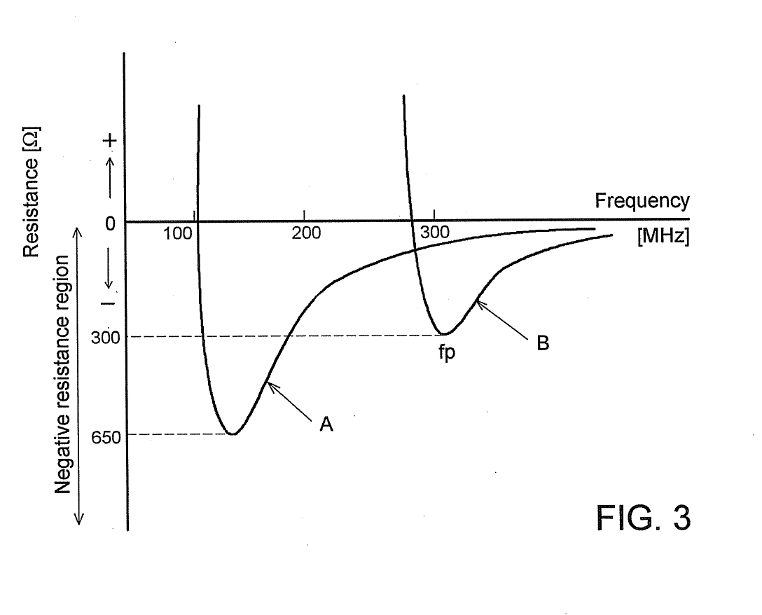

With such an arrangement, the oscillator circuit (CF5036D1) viewed from the opposite ends of crystal element 2 before inductor L is connected thereto has negative resistance characteristics as shown by the curve A in FIG. 3. Here, it is assumed that crystal element 2 has an equivalent parallel capacitance of 2 pF. That is, the negative resistance region lies in the range from about 100 MHz, and the curve reaches the maximum negative resistance (650Ω) in the vicinity of 120 MHz and then gradually decreases.

In this case, in the 300-MHz band, for example, at a frequency of 325 MHz, the negative resistance is about 90Ω. In the case of the oscillation at frequency of 325 MHz in the third overtone mode of crystal element 2, the frequency of about 110 MHz of the fundamental wave falls within the negative resistance region, and therefore, the fundamental wave oscillation cannot be adequately suppressed. In addition, the crystal impedance (C1) of crystal element 2 in the third overtone oscillation is about 50 to 60Ω, and therefore, the circuit margin for oscillation is low when the negative resistance is 90Ω. For example, if the C1 of crystal element 2 becomes equal to or higher than 90Ω because of aging or the like, the third overtone oscillation stops. Thus, the long-term reliability of the oscillation is low.

On the other hand, according to this embodiment, inductor L is added to form a parallel resonant circuit, and the parallel resonance frequency is set higher than oscillation frequency f1 (110 MHz) of the fundamental wave as shown by the curve B in FIG. 2. In this case, the impedance of the parallel resonant circuit dominates the impedance of the oscillator circuit in the resonance frequency region viewed from the opposite ends of crystal element 2. Thus, if parallel resonance frequency fp is set at 300 MHz, for example, the impedance reaches the maximum value of about 300Ω at the frequency of 300 MHz, and accordingly, the negative resistance also reaches the maximum value (300Ω) at the frequency of 300 MHz. Thus, the oscillation of the fundamental wave (f1, 100 MHz) of crystal element 2 is suppressed with reliability. At the oscillation frequency (300 MHz) in the third overtone mode, the negative resistance is about 200Ω. The negative resistance (200Ω) is more than three times the C1 (50 to 60Ω) of crystal element 2 in the third overtone oscillation. Thus, the circuit margin is sufficient, and the long-term reliability is ensured.

What is claimed is:

1. A third overtone crystal oscillator, comprising:
an oscillator IC; and
a crystal element,
wherein the oscillator IC comprises:
an transistor for oscillation which is grounded at an emitter thereof, a bias resistor being connected between a collector and a base of the transistor, and a constant current being supplied from a constant current source to a junction point between the collector and the bias resistor;
a first capacitor for oscillation connected to the base via a dc blocking capacitor and to a ground potential; and
a second capacitor for oscillation connected between the collector and the ground potential,
wherein one end of the crystal element is connected to a non-grounded end of the first capacitor while the other end of the crystal element is connected to a non-grounded end of the second capacitor,
wherein an inductor, which forms a parallel resonant circuit with the first capacitor, is provided as a discrete element separated from the oscillator IC, and
wherein a parallel resonance frequency of the parallel resonant circuit formed by the first capacitor and the inductor is set higher than an oscillation frequency of a fundamental wave of the crystal element and lower than an oscillation frequency of a third overtone of the crystal element.

2. The crystal oscillator according to claim 1, wherein the crystal element comprises an AT-cut crystal unit.
